(19) United States
(12) Patent Application Publication
(10) Pub. No.: US 2006/0194386 A1
(43) Pub. Date: Aug. 31, 2006

(54) Method and apparatus for supporting port aggregation of serial attached SCSI wide ports via virtual ports

(75) Inventors: Xuebin Yao, Austin, TX (US); Gary Kotzur, Austin, TX (US); Sompong Paul Olarig, Pleasanton, CA (US)

Correspondence Address: BAKER BOTTS, LLP, 910 LOUISIANA, HOUSTON, TX, 77002-4995, US

(73) Assignee: Dell Products L.P.

(21) Appl. No.: 11/065,972

(22) Filed: Feb. 25, 2005

(51) Int. Cl. H01L 21/336

(52) U.S. Cl. 438/257

(57) ABSTRACT

An SAS RAID adapter comprises an input-output processor (IOP) and at least two SAS input-output controllers (IOCs). Wherein SAS links coupled to each of the IOCs form “virtual ports” in order to increase performance and maintain availability. The virtual ports across the at least two IOCs have wide port SAS link capability so as to provide performance enhancements similar to a standard SAS wide port. Even if a single IOC failure occurs, downshifting to N/2 links is provided with degraded aggregated bandwidth (data throughput) instead of a failover and/or system shutdown.

### BACKGROUND OF THE INVENTION TECHNOLOGY

1. Field of the Invention

The present disclosure relates generally to information handling systems and, more particularly, to a method and apparatus for supporting port aggregation of serial attached SCSI wide ports via virtual ports in the information handling system.

2. Description of the Related Art

As the value and use of information continues to increase, individuals and businesses seek additional ways to process and store information. One option available to users are information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems, e.g., computer, personal computer workstation, portable computer, computer server, print server, network router, network hub, network switch, storage area network disk array, RAID disk system and telecommunications switch.

Storage area network and server systems using redundant array of independent disks (RAID) have been effectively using Serial Attached SCSI (SAS) (SCSI is an abbreviation for “Small Computer System Interface”) for transfer of data and control information among the various disk drives and computer servers. SAS offers full duplex, dual-ported serial connections that support the most stringent of high-availability requirements. SAS uses point-to-point serial connections that may be easily scalable for high-speed shared bandwidth connections by integrating the multiple-ported serial connections on a very large scale integrated circuit (VLSI) device.

A RAID adapter of a storage server system may use an input-output processor (IOP) and a single SAS input-output controller (IOC). While a SAS wide port will sustain the connection if n−1 link fail, the IOC presents a single point of failure. If an IOC fails, the entire SAS storage subsystem is affected, resulting in down time of the information handling system. Since SAS is generally targeted for use in high end enterprise information handling systems, any system down time will result in financial loss for critical business applications, increase maintenance costs and reduce customer satisfaction.

Heretofore, high availability of an enterprise information handling system has been achieved through redundancy of hardware, e.g., clustering comprising multiple RAID adapters, host bus adapters (HBAs), etc., for eliminating a single point failure. However, hardware redundancy, e.g., clustering, etc., is not cost effective and requires complicated failover/load-balancing software support. In addition, cache memory mirroring is required to maintain data coherency between the separate redundant RAID adapters.

Therefore, there is a need for a simplified and lower cost method and apparatus for improving the reliability and availability of an information handling system utilizing serial attached SCSI (SAS) ports when eliminating the possibility of a single point failure in critical data transfer and storage operations.

### SUMMARY OF THE INVENTION

The present invention remedies the shortcomings of the prior art by providing a method and apparatus for an information handling system, e.g., a multi-server and/or RAID storage, that comprises an input-output processor (IOP), e.g., for a SAS RAID adapter, etc., coupled to at least two SAS input-output controllers (IOCs). Wherein SAS links coupled to each of the IOCs form “virtual ports” in order to increase performance and maintain availability such as Fibre Channel (FC) link aggregation between, for example but not limited to, switches using vendor proprietary implementations, or GbE 802.3ad GbE link aggregation: IEEE Draft P802.3ad, “Supplemental to Carrier Sense Multiple Access with Collision Detection (CSMA/CD) Access Method and Physical Layer Specifications: Link Aggregation,” hereby incorporated by reference herein for all purposes. The virtual ports across the at least two IOCs have wide port SAS link capability so as to provide performance enhancement similar to a standard SAS wide port as defined by the SAS specification, incorporated by reference herein for all purposes. Even if a single IOC failure occurs, the present invention provides for downshifting to N/2 links with degraded aggregated bandwidth (data throughput) instead of a failover and/or system shutdown.

According to a specific embodiment, an IOP of a SAS RAID adapter comprises a RAID stack, an applications layer, a transport layer and a virtual SAS port layer. The IOP is coupled to at least two SAS IOCs, wherein each SAS IOC comprises an applications layer, a transport layer, a SAS port layer, a SAS link layer, a SAS PHY layer and a SAS physical layer. The IOC SAS physical layer is adapted for coupling to SAS expander and/or target devices. SAS operation and SAS layer details are more fully defined in the American National Standards Institute (ANSI) draft standards: Serial Attached SCSI (SAS) and Serial Attached SCSI-1.1 specification draft revision 5, Jul. 26, 2004, ISO/IEC 14776-151:200x, ANSI INCITS.***.200x (SAS-1.1) (hereinafter SAS draft standards), as described in the latest revision working documents of Project T10/1562-D and Project T10.1601-D of the T10 Accredited Standards Committee of INCITS (International Committee of Information Technology Standards), all of which are hereby incorporated by reference herein for all purposes.

According to the SAS draft standards, the SAS physical layer comprises two sets of differential lines, one receive set and one transmit set (4-wires total). The SAS PHY layer connects differential transmitter and receiver circuits to the SAS physical layer which defines the cable, connector and transceiver (receiver/transmitter) characteristics. An SAS external connector accepts up to four (4) physical links, while the connecting cable may couple from one (1) to four (4) physical links. There are two types of ports: (1) narrow ports which communicate over narrow links and contain only one transmit/receive pair per port, and (2) wide ports which communicate over wide links and contain more than one transmit/receive pair (e.g., data bus, data path, etc.). The wide ports reside in the SAS PHY layer and the narrow ports reside in the SAS physical layer.

The SAS link layer interfaces between the SAS PHY layer and the SAS port layer. The SAS link layer controls the SAS PHY layer to manage connections with SAS devices, including but not limited to SSP, STP and SMP protocols. The SAS port layer communicates with the SAS link layer and associated SAS PHY layer. The transport layer interfaces between the SAS port layer and the application layer. Generally, there is one transport layer for each type of application layer.

The IOP virtual SAS port layer is coupled to each IOC SAS port layer. The IOP virtual SAS port layer has its own IOP transport layer and IOP application layer. This IOP application layer is coupled to the RAID stack of the IOP. The RAID stack is also coupled to each of the IOC application layers.

The at least two IOCs may be combined with the associated IOP into a single module, e.g., single card or blade. A virtual SAS port layer, transportation layer and application layer are added to the IOP. These layers may perform similar functions as do the SAS port, transportation and application layers in each of the IOCs. The IOP virtual SAS port layer may be adapted to handle SAS multi-link synchronization for virtual wide ports across multiple IOCs. There is direct access between each IOC port layer and the IOP virtual SAS port layer via the virtual wide ports. The IOP may also be coupled to each IOC via standard SAS ports. Thus, each IOC is coupled to the IOP with both a standard SAS port and a virtual SAS port.

A SAS expander and/or target device is coupled to the at least two IOCs through wide ports, e.g., more than one transmit/receive pair (4 pairs from each IOC as shown in FIG. 3). If N−1 (where N is the number of IOCs) of the at least two IOCs should fail then the IOP may still communicate with the SAS expander and/or target device, but with slower data throughput (only ports of the operational IOC(s) would be functional). However, this results in only a “fail down,” not a fail over. Also substantially no additional hardware is required for the present invention, unlike failover redundant systems. The IOC application, transport, SAS port, SAS link, SAS PHY and SAS physical layers may be implemented in firmware, software, and/or hardware, or any combination thereof. Preferably the IOC application, transport, SAS port, SAS link, SAS PHY layers may be implemented in firmware and the SAS physical layer in hardware. The IOP application, transport and virtual SAS port layers may be implemented in firmware, software, and/or hardware, or any combination thereof, preferably in firmware. Coupling between the IOP and associated IOCs may be through hardware buses (separate integrated circuits on a printed circuit board(s), metallic bus connections in a very large scale integrated circuit (VLSI), and/or software instructions in a combination IOP/IOC VLSI microcontroller, microprocessor, application specific integrated circuit (ASIC), programmable logic array (PLA), etc.

It is contemplated and within the scope of the present invention that any type of storage controller, e.g., IOP and IOC, RAID-On-Chip (ROC), etc., may benefit from the teaching of the present disclosure.

A technical advantage of the present invention is increasing performance through port aggregation instead of load balancing. Still another technical advantage is no failover/load balancing required for redundant operation. Yet another technical advantage is low latency. Another technical advantage is transparent fail-down instead of more complex failover. Another technical advantage is simplified hardware requirements. Yet another technical advantage is redundancy with write-back is provided without need for cache memory mirroring or extra data communications paths for cache memory coherency. Still another technical advantage is flexibility in having additional data links available for other uses in both internal and external applications and to also provide for internal redundancy. Other technical advantages should be apparent to one of ordinary skill in the art in view of what has been disclosed herein.

### BRIEF DESCRIPTION OF THE DRAWINGS

A more complete understanding of the present disclosure and advantages thereof may be acquired by referring to the following description taken in conjunction with the accompanying drawings wherein:

FIG. 1 is a schematic block diagram of an exemplary embodiment of an information handling system; according to teachings of the present disclosure;

FIG. 2 is a schematic block diagram of prior technology SAS wide-port connectivity with multi-pathing; and

FIG. 3 is a schematic block diagram of SAS wide-port connectivity using virtual port access across at least two IOCs, according to teachings of the present disclosure.

The present invention may be susceptible to various modifications and alternative forms. Specific exemplary embodiments thereof are shown by way of example in the drawing and are described herein in detail. It should be understood, however, that the description set forth herein of specific embodiments is not intended to limit the present invention to the particular forms disclosed. Rather, all modifications, alternatives, and equivalents falling within the spirit and scope of the invention as defined by the appended claims are intended to be covered.

### DETAILED DESCRIPTION OF SPECIFIC EMBODIMENTS

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU), hardware or software control logic, read only memory (ROM), and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

Referring now to the drawings, the details of a specific exemplary embodiment of the present invention are schematically illustrated. Like elements in the drawings will be represented by like numbers, and similar elements will be represented by like numbers with a different lower case letter suffix.

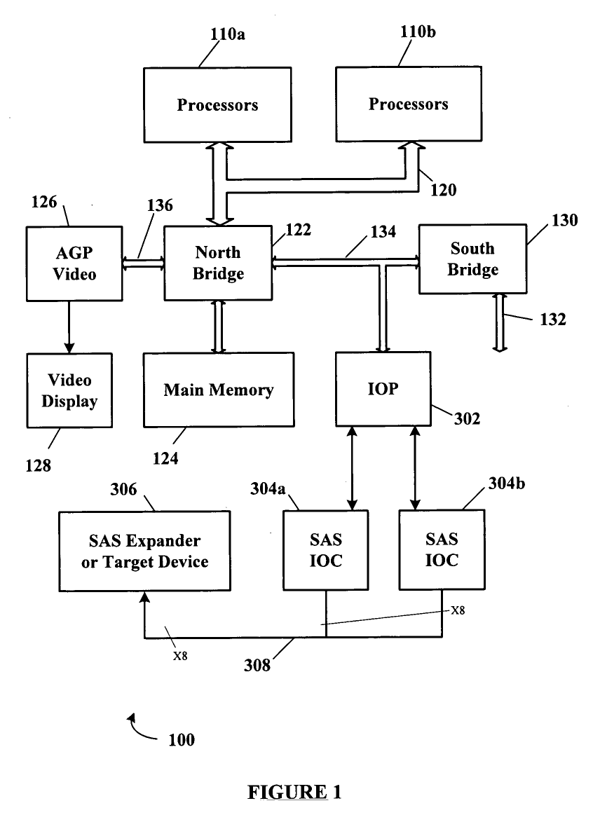

Referring to FIG. 1, depicted is an information handling system having electronic components mounted on at least one printed circuit board (PCB) (motherboard) and communicating data and control signals therebetween over signal buses. In one embodiment, the information handling system is a computer system. The information handling system, generally referenced by the numeral 100, comprises a processor(s) 110 coupled to a host bus(es) 120. A north bridge 122, which may also be referred to as a memory controller hub or a memory controller, is coupled to a main system memory 124. The north bridge 122 is coupled to the system processor(s) 110 via the host bus(es) 120. The north bridge 122 is generally considered an application specific chip set that provides connectivity to various buses, and integrates other system functions such as a memory interface. For example, an Intel 820E and/or 815E chip set, available from the Intel Corporation of Santa Clara, Calif., provides at least a portion of the north bridge 122. The chip set may also be packaged as an application specific integrated circuit (ASIC). The north bridge 122 typically includes functionality to couple the main system memory 124 to other devices within the information handling system 100. Thus, memory controller functions such as main memory control functions typically reside in the north bridge 122. In addition, the north bridge 122 provides bus control to handle transfers between the host bus 120 and a second bus(es), e.g., PCI bus 134, AGP bus 136 coupled to a video graphics interface 126 which drives a video display 128. A second bus(es) 132 may also comprise other industry standard buses or proprietary buses, e.g., ISA, SCSI, USB buses through a south bridge(s) (bus interface) 130. An input-output processor (IOP) 302 of a SAS RAID adapter is coupled to the north bridge 122. At least two SAS input-output controllers (IOCs) 304 are coupled to the IOP 302. The at least two IOCs 304 are coupled to an SAS expander or target device 306 through, for example, a plurality of SAS physical links 308 (eight shown).

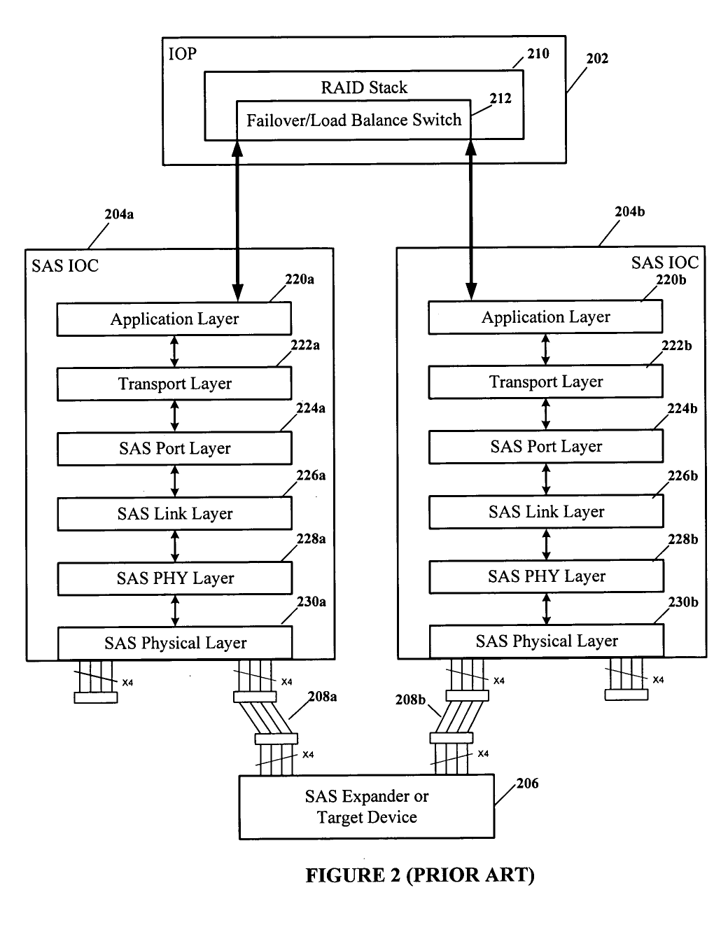

Referring to FIG. 2, depicted is a schematic block diagram of prior technology SAS wide-port connectivity with multi-pathing. An RAID adapter input-output processor (IOP) 202 comprises a RAID stack 210 and a failover/load balance switch 212. Two SAS input-output controllers (IOCs) 204 are coupled to the IOP 210 through the switch 212. The switch 212 is used by the IOP 202 for load balancing between the two IOCs 204, or in the event of a failure of one of the IOCs 204, total operation to the remaining good IOC 204. Each IOC 204 is comprised of an application layer 220, a transport layer 222, a SAS port layer 224, a SAS link layer 226, a SAS PHY layer 228 and a SAS physical layer 230. When both IOCs 204 are operational, an SAS expander or target device 206 (e.g., raid disk array) has maximum data throughput over both SAS wide port links 206. When one of the IOCs 204 is down, only one of the SAS wide port links 208 is operational. The RAID adapter shown in FIG. 2 requires complicated failover/load-balancing software support, and, in addition, may need cache mirroring to maintain data coherency between separate RAID adapters, all costly and complex.

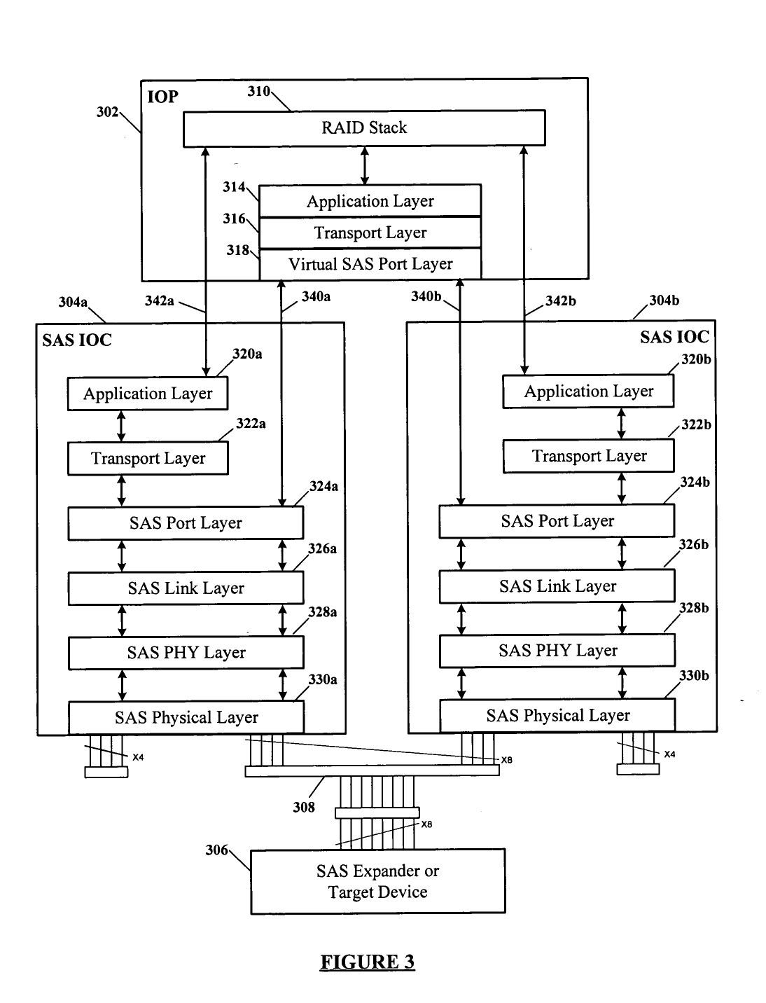

Referring now to FIG. 3, depicted a schematic block diagram of SAS wide-port connectivity using virtual port access across at least two IOCs, according to an exemplary embodiment of the present disclosure. A SAS RAID adapter of an information handling system 100 comprises an input-output processor (IOP) 302 and at least two SAS input-output controllers (IOCs) 304. Wherein SAS links from the at least two IOCs 304 form “virtual ports” in order to increase performance and maintain availability such as Fibre Channel (FC) link aggregation between, for example but not limited to, switches using vendor proprietary implementations, or GbE 802.3ad (Gigabit Ethernet) link layer aggregation. The Virtual ports across the at least two IOCs 304 have wide port SAS link capability so as to provide performance enhancement similar to a standard SAS wide port as defined by the SAS specification, incorporated by reference herein for all purposes. Even if a single IOC 304 failure occurs, the present invention provides for downshifting to N/2 links with degraded aggregated bandwidth (data throughput) instead of a failover and/or system shutdown.

The IOP 302 comprises a RAID stack 310, an applications layer 314, a transport layer 316 and a virtual SAS port layer 318. The IOP 302 is coupled to at least two SAS IOCs 304, wherein each SAS IOC 304 comprises an applications layer 320, a transport layer 322, a SAS port layer 324, a SAS link layer 326, a SAS PHY layer 328 and a SAS physical layer 330. The IOC SAS physical layer 330 is adapted for coupling to SAS expander and/or target devices 306. SAS operation and SAS layer details are more fully defined in the American National Standards Institute (ANSI) draft standards: Serial Attached SCSI (SAS) and Serial Attached SCSI-1.1 specification draft revision 5, Jul. 26, 2004, ISO/IEC 14776-151:200x, ANSI INCITS.***.200x (SAS-1.1) (hereinafter SAS draft standards), as described in the latest revision working documents of Project T10/1562-D and Project T10.1601-D of the T10 Accredited Standards Committee of INCITS (International Committee of Information Technology Standards), all of which are hereby incorporated by reference herein for all purposes.

According to the aforementioned SAS draft standards, the SAS physical layer 330 comprises two sets of differential lines, one receive set and one transmit set (4-wires total). The SAS PHY layer 328 connects differential transmitter and receiver circuits to the SAS physical layer 330 which defines the cable, connector and transceiver (receiver/transmitter) characteristics. An SAS external connector accepts up to four (4) physical links, while the connecting cable may couple from one (1) to four (4) physical links. There are two types of ports: (1) narrow ports which communicate over narrow links and contain only one transmit/receive pair per port, and (2) wide ports which communicate over wide links and contain more than one transmit/receive pair (e.g., data bus, data path, etc.). The wide ports reside in the SAS PHY layer and the narrow ports reside in the SAS physical layer.

The SAS link layer 326 interfaces between the SAS PHY layer 328 and the SAS port layer 324. The SAS link layer 326 controls the SAS PHY layer 328 to manage connections with SAS devices 306, including but not limited to SSP, STP and SMP protocols. The SAS port layer 324 communicates with the SAS link layer 326 and associated SAS PHY layer 328. The transport layer 322 interfaces between the SAS port layer 324 and the application layer 320. Generally, there is one transport layer 322 for each type of application layer 320.

The IOP virtual SAS port layer 318 is coupled to each IOC SAS port layer 324. The IOP virtual SAS port layer 318 has its own IOP transport layer 316 and IOP application layer 314. This IOP application layer 314 is coupled to a RAID stack 310 of the IOP 302. The RAID stack 310 is also coupled to each of the IOC application layers 320.

The at least two IOCs 304 may be combined with the associated IOP 302 into a single module, e.g., single card or blade (not shown). The virtual SAS port layer 318, transportation layer 316 and application layer 314 are added to the IOP 302, according to specific embodiments. These layers may perform similar functions as do the SAS port layer 324, transportation layer 322 and application layer 320 in each of the at least two IOCs 304. The IOP virtual SAS port layer 318 may be adapted to handle SAS multi-link synchronization for virtual wide ports across multiple IOCs 304. There is direct access between each IOC port layer 324 and the IOP virtual SAS port layer 318 via virtual wide ports 340. The IOP 302 may also be coupled to each IOC 304 via standard SAS ports 342. Thus, each IOC 304 is coupled to the IOP 302 with both a standard SAS port 342 and a virtual port 340.

A SAS expander and/or target device 306 is coupled to the at least two IOCs 304 through wide ports 308, e.g., more than one transmit/receive pair (4 pairs from each IOC 304 as shown in FIG. 3). If N-1 (where N is number of IOCs) of the at least two IOCs 304 should fail then the IOP 302 may still communicate with the SAS expander and/or target device 306, but with slower data throughput (only ports of the operational IOC(s) 304 would be functional). However, this results in only a “fail down,” not a fail over. Also substantially no additional hardware is required for the present invention, unlike failover redundant systems. The IOC application, transport, SAS port, SAS link, SAS PHY and SAS physical layers may be implemented in firmware, software, and/or hardware, or any combination thereof. Preferably the IOC application, transport, SAS port, SAS link, SAS PHY layers may be implemented in firmware and the SAS physical layer in hardware. The IOP application, transport and virtual SAS port layers may be implemented in firmware, software, and/or hardware, or any combination thereof, preferably in firmware. Coupling between the IOP 302 and associated IOCs 304 may be through hardware buses (separate integrated circuits on a printed circuit board(s), metallic bus connections in a very large scale integrated circuit (VLSI), and/or software instructions in a combination IOP/IOC VLSI microcontroller, microprocessor, application specific integrated circuit (ASIC), programmable logic array (PLA), etc.

It is contemplated and within the scope of the present invention that any type of storage controller, e.g., IOP and IOC, RAID-On-Chip (ROC), etc., may benefit from the teaching of the present disclosure.

The invention, therefore, is well adapted to carry out the objects and to attain the ends and advantages mentioned, as well as others inherent therein. While the invention has been depicted, described, and is defined by reference to exemplary embodiments of the invention, such references do not imply a limitation on the invention, and no such limitation is to be inferred. The invention is capable of considerable modification, alteration, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects.

What is claimed is:

1. A method for supporting port aggregation of serial attached SCSI (SAS) wide ports via virtual ports in an information handling system, said method comprising the steps of:
providing an input-output processor (IOP) having an IOP stack, an IOP applications layer, an IOP transport layer and an IOP virtual SAS port layer,
wherein the IOP stack is coupled to the IOP applications layer, the IOP applications layer is coupled to the IOP transport layer, and the IOP transport layer is coupled to the IOP virtual SAS port layer;
providing at least two input-output controllers (IOCs), each of the at least two IOCs having an IOC application layer, an IOC transport layer, an IOC SAS port layer, an IOC SAS link layer, an IOC SAS PHY layer, and an IOC SAS physical layer,
wherein the IOP stack is coupled to the IOC application layer, the IOC application layer is coupled to the IOC transport layer, the IOC transport layer is coupled to the IOC SAS port layer, IOC SAS port layer is coupled to the IOC SAS link layer, the IOC SAS link layer is coupled to the IOC SAS PHY layer, and the IOC SAS PHY layer is coupled to the IOC SAS physical layer; and
providing a plurality of data communications links from each of the at least two IOCs adapted, wherein the data communications links are adapted for coupling to an SAS device so that as long as at least one IOC is functioning there is data communications to and from the SAS device.

2. The method according to claim 1, wherein the IOP is an IOP for a RAID adapter.

3. The method according to claim 1, wherein the plurality of data communications links from the IOC SAS physical layer are a plurality of SAS narrow ports.

4. The method according to claim 1, wherein the plurality of data communications links from the IOC SAS PHY layer are a plurality of SAS wide ports.

5. The method according to claim 1, wherein the SAS link layer controls the SAS PHY layer for managing a connection with the SAS device.

6. The method according to claim 5, wherein the SAS link layer uses an SSP protocol.

7. The method according to claim 5, wherein the SAS link layer uses an STP protocol.

8. The method according to claim 5, wherein the SAS link layer uses an SMP protocol.

9. The method according to claim 1, wherein the IOP virtual SAS port layer handles SAS multi-link synchronization for virtual wide ports across the at least two IOCs.

10. The method according to claim 1, wherein each of the at least two IOCs is coupled to the IOP with both a standard SAS port and a virtual SAS port.

11. An apparatus for supporting port aggregation of serial attached SCSI (SAS) wide ports via virtual ports in an information handling system, comprising:
an input-output processor (IOP) having an IOP stack, an IOP applications layer, an IOP transport layer and an IOP virtual SAS port layer, wherein the IOP stack is coupled to the IOP applications layer, the IOP applications layer is coupled to the IOP transport layer, and the IOP transport layer is coupled to the IOP virtual SAS port layer;
at least two input-output controllers (IOCs), each of the at least two IOCs having an IOC application layer, an IOC transport layer, an IOC SAS port layer, an IOC SAS link layer, an IOC SAS PHY layer, and an IOC SAS physical layer, wherein the IOP stack is coupled to the IOC application layer, the IOC application layer is coupled to the IOC transport layer, the IOC transport layer is coupled to the IOC SAS port layer, IOC SAS port layer is coupled to the IOC SAS link layer, the IOC SAS link layer is coupled to the IOC SAS PHY layer, and the IOC SAS PHY layer is coupled to the IOC SAS physical layer; and
a plurality of data communications links from each of the at least two IOCs, wherein the data communications links are adapted for coupling to an SAS device so that as long as at least one IOC functions there is data communications to and from the SAS device.

12. The apparatus according to claim 11, wherein the IOP is an IOP for a RAID adapter.

13. The apparatus according to claim 12, wherein the SAS device is a redundant array of independent disks (RAID).

14. The apparatus according to claim 11, wherein the plurality of data communications links from the IOC SAS physical layer are a plurality of SAS narrow ports, each of the plurality of SAS narrow ports comprising one transmit/receive pair.

15. The apparatus according to claim 11, wherein the plurality of data communications links from the IOC SAS PHY layer are a plurality of SAS wide ports, each of the plurality of SAS wide ports comprising a plurality of transmit/receive pairs.

16. The apparatus according to claim 11, wherein the IOC application layer, the IOC transport layer, the IOC SAS port layer, and the IOC SAS link layer function as firmware in each of the at least two IOCs.

17. The apparatus according to claim 11, wherein the IOP virtual SAS port layer handles SAS multi-link synchronization for virtual wide ports across the at least two IOCs.

18. The apparatus according to claim 11, wherein each of the at least two IOCs is coupled to the IOP with both a standard SAS port and a virtual SAS port.

19. A method for supporting port aggregation of serial attached SCSI (SAS) wide ports via virtual ports in an information handling system, said method comprising the steps of:
providing a storage controller having a stack, a first applications layer, a first transport layer and a virtual SAS port layer, a plurality of second application layers, a plurality of second transport layers, a plurality of SAS port layers, a plurality of SAS link layers, a plurality of SAS PHY layers, and a plurality of SAS physical layers;
wherein the stack is coupled to the first applications layer and the plurality of second applications layers, the first applications layer is coupled to the first transport layer, and the first transport layer is coupled to the virtual SAS port layer; each of the plurality of second applications layers is coupled to respective ones of the plurality of second transport layers, each of the plurality of second transport layers is coupled to respective ones of the plurality of SAS port layers, each of the plurality of SAS port layers is coupled to respective ones of the plurality of SAS link layers, each of the plurality of SAS link layers is coupled to respective ones of the plurality of SAS PHY layers, and each of the plurality of SAS PHY layers is coupled to respective ones of the plurality of SAS physical layers; and
providing a plurality of data communications links from each of the plurality of SAS physical layers, wherein the data communications links are adapted for coupling to an SAS device so that as long as at least one set of respective ones of the plurality of second applications layers, second transport layers, SAS port layers, SAS link layers, SAS PHY layers and SAS physical layers are functioning there is data communications to and from the SAS device.

20. The method according to claim 19, wherein the storage controller is a RAID-on-chip (ROC) controller.

21. The method according to claim 19, wherein the storage controller comprises a input-output processor (IOP) and a plurality of input-output controllers (IOCs).

22. An apparatus for supporting port aggregation of serial attached SCSI (SAS) wide ports via virtual ports in an information handling system, comprising:
a storage controller having a stack, a first applications layer, a first transport layer and a virtual SAS port layer, a plurality of second application layers, a plurality of second transport layers, a plurality of SAS port layers, a plurality of SAS link layers, a plurality of SAS PHY layers, and a plurality of SAS physical layers;
wherein the stack is coupled to the first applications layer and the plurality of second applications layers, the first applications layer is coupled to the first transport layer, and the first transport layer is coupled to the virtual SAS port layer; each of the plurality of second applications layers is coupled to respective ones of the plurality of second transport layers, each of the plurality of second transport layers is coupled to respective ones of the plurality of SAS port layers, each of the plurality of SAS port layers is coupled to respective ones of the plurality of SAS link layers, each of the plurality of SAS link layers is coupled to respective ones of the plurality of SAS PHY layers, and each of the plurality of SAS PHY layers is coupled to respective ones of the plurality of SAS physical layers; and
a plurality of data communications links from each of the plurality of SAS physical layers, wherein the data communications links are adapted for coupling to an SAS device so that as long as at least one set of respective ones of the plurality of second applications layers, second transport layers, SAS port layers, SAS link layers, SAS PHY layers and SAS physical layers are functioning there is data communications to and from the SAS device.

23. The apparatus according to claim 22, wherein the storage controller is a RAID-on-chip (ROC) controller.

24. The apparatus according to claim 22, wherein the storage controller comprises a input-output processor (IOP) and a plurality of input-output controllers (IOCs).
